(19) United States
(12) Patent Application Publication
(10) Pub. No.: US 2010/0326493 A1
(43) Pub. Date: Dec. 30, 2010

(54) PHOTOVOLTAIC APPARATUS UTILIZING INTERNAL REFLECTION

(76) Inventor: Dillon Carter Sherman, Tavares, FL (US)

Correspondence Address: IPLA P.A., 3550 WILSHIRE BLVD., 17TH FLOOR, LOS ANGELES, CA, 90010, US

(21) Appl. No.: 12/823,952

(22) Filed: Jun. 25, 2010

Related U.S. Application Data
(60) Provisional application No. 61/269,724, filed on Jun. 29, 2009.

(51) Int. Cl. H01L 31/052

(52) U.S. Cl. 136/246

(57) ABSTRACT

A photovoltaic apparatus comprising: a semi-transparent photovoltaic panel to absorb a portion of the photons and to produce electrical energy, wherein the panel has a first conducting surface on the top thereof facing upwards and a second conducting surface at the bottom thereof facing downwards; and a bottom mirror and a top mirror to reflect the remaining photons from the photovoltaic panel, whereby the remaining photons bounce up and down between the top and bottom mirrors to increase production of the electrical energy.

### CROSS REFERENCE

This application claims priority of Provisional Application No. 61/269,724 filed Jun. 29, 2009.

### BACKGROUND OF THE INVENTION

This Invention relates to a photovoltaic apparatus that uses internal reflection or meets the specifications disclosed within this document.

Fully-transparent photovoltaic (PV) materials allow for PV elements to be implemented in far more varied areas, and reflects 0% of the light it receives. Unfortunately it is only as efficient as the maximum amount of light it can convert per quantity of light received.

Usage of solid mirrors—light not absorbed initially by the PV elements will bounce off the mirrors giving the light a second chance to be absorbed by the PV elements (photovoltaic panel) and produce electricity. The present invention suggests the usage of semi-transparent mirrors that allow some photon light to pass thru, rather than all light being reflected. Usage of 0% light reflecting transparent material (of the non photovoltaic variety) such as, but not limited to: glass, made of this material will pass 100% of the light received through it with out reflecting any light off any face coming from any angle.

Usage of convex, Fresnel, or chemically blazed lenses, allows for PV elements to be implemented in far more varied areas, and allows for light coming from many angles to be refracted into the cell which allows for a greater period of time with which to convert said light. Inadvertently the lens(es) destroy the need to design a spot for the cell, for the cell has been inadvertently been designed around most if not any sun-facing spot.

Wave-specificity and multilayer format—layers of different wave-specific materials absorb/convert their specific light wave, and only that wave, allowing light received to be absorbed/converted far more completely. Transparent conducting oxides (TCO's) can be used in place of regular contacts that partially block sunlight and cannot fully cover the photovoltaic panel, whereas TCO's do not block sunlight and may cover the entire PV element because the TCO's allow light photons to pass thru them. UV protection—Protection from UV rays has been proven to extend PV cell's life and the longevity of the cost efficiency of the cell.

U.S. Pat. No. 4,663,495 states that the back contact is fabricated to maximize transmission of radiation. It also claims the front electrode, the semi conductive layer and the back electrode are fabricated to enhance transmission of radiation by the module. Nowhere does it explicitly state that the contacts work to reduce the transmittance of light by the cell. Also U.S. Pat. No. 4,663,495 never states that Mirrors could be placed at the sides of the apparatus and does not disclose purposely exploiting mirror contacts. The present invention adds using the Semi-silvered mirrors or solid mirrors as the bottom reflector, top reflector, and, if desired, the side reflectors.

Their TCO is not Tin Dioxide. They claim a combined solar panel/solar thermal apparatus but never explicitly state what the heated fluid is used for, where the present invention is design for heat transfer that is intrinsicly different from theirs, in design, work, and increased efficiency.

U.S. Pat. No. 4,663,495 claims a method of utilizing a thin film photovoltaic module to filter solar radiation entering a structure having a plurality of walls defining an interior volume, but not as the present design specifies. Also they aren't mirrored walls, or walls that serve as contacts in context of our product.

### SUMMARY OF THE INVENTION

This invention is contrived to overcome the conventional disadvantages. An object of this invention is to utilize semi-silvered mirrors to allow light through on one side, and on the other semi-silvered side, a majority of the light is reflected back where it can be absorbed by the. It will give a convenient entrance, but hesitant exit for light into/out of the PV elements.

Mirrored convex, blazed, and/or Fresnel lens(es)—given the chance that light might be refracted by the lens(es) but not into the PV elements, the mirror(s) will ensure, at least partially for that light to be reflected into the PV element.

Usage of mirrors—light not absorbed will bounce off the mirrors giving the light a second chance to be absorbed and making light pass through the cell in at least 2 directions at any given time. Mirrors also serving as current conductors, which allows less material to be used to make panels, increasing cost efficiency. Resistors—will serve to separate current conductors and electricity loss due to environmental exposure. Convection cooling, convection coolant, and convection cooling tubes—by cooling the cell, thereby heating the coolant, the cell's longevity of usage and optimal cost efficiency are increased. Multiple usage of depleted coolant—hot coolant will move faster through its container due to physics, thus depleted (heated) coolant could be used to turn a turbine or in a generator. Moreover, if that coolant happens to be water, it could be used as, but not limited to, heated pool, and bath water.

Fiber optic wires can be used as wave guides for the light photons. If you used fiber optics as waveguides, you could have the PV apparatus be fully mirrored, save for the holes in the mirrors where the fiber optic wire(s) empty their photons into the cell. This would allow the PV element to be placed anywhere convenient and it would give those PV elements a possibly greater amount of time with which to convert a possibly greater quantity of light received/usable.

A wave splitter and/or lens(es) used as a UV filterer along with their obvious usage, they could also be made to filter out UV waves, which would extend life and optimal cost efficiency of the cell. Lens made of fully transparent PV materials, along with the lens(es) obvious usage, they could also be used to generate electricity whilst upholding their original purpose.

PV layers also serving as wave guides—PV layers made of materials so differential from the next that if the purpose of said layers were to be wave specific, the wave specific to that layer would be trapped in said layer while all other useful waves would pass straight through said layer and all other layers non-specific to a particular wave included in a given wave group.

Inverted PV layers—layers of PV material that are placed so that the corresponding part of a PV layer is facing the neighboring PV layer and such that the first layer of PV material has the sun reactant side facing the sun and such that the last layer of PV material has the sun reactant side facing away from the sun unless its spacial relation in regards to the position of the sun were changed to make the last layer the sun facing layer.

TCO's placed between the corresponding inverted PV layer parts—this will help to separate the currents between the PV layer sides and allow for electricity to flow more freely throughout the cell, allowing for more readily absorbed electricity to be available.

Light-reflecting resistors—resistors that would be useful in light reflection while still upholding the role of a resistor would be ideal in internal PV cell circuitry in that by allowing resistors to be placed at a place where light reflection is necessary and where opposite charges might interact the PV layers may be smaller, closer together, and more abundant. That is given layers are present that need separation, and given light need be reflected at all.

Cooling—it has been proven cooling components disclosed within this document are beneficial to said components. Usage of a 2-D and/or 3-D PV wire grid—“wires” of PV material complete with charged PV layer, + charged layer, and the outer and core contacts. The wires may be semi- or fully transparent and with or with out the usage of TCO's. if not created initially as such, the wires are then connected such that they are merged at all layers of the wires and form a 2-D and/or 3-D PV wire grid. This could be implemented as front porch mosquito and bug guards while serving as a “window of sorts” that allows fresh air through.

Usage of a 2-D and/or 3-D PV wire grid fully suspended and/or encased in a transparent medium except for where the contacts send/receive electricity—able to be implemented as sliding glass doors, screened doors, “security windows” (windows that are reinforced, or have an electrical current running through them so that when the current is broken such as when the window is broken an alarm will be triggered).

A photovoltaic apparatus comprises various components including transparent photovoltaic material possibly in cell or panel form. Semi-silvered mirror possibly placed at the bottom and/or top of the Transparent Photovoltaic material. Solid mirror(s) possibly placed at the bottom of the Transparent Photovoltaic Material (in conjunction with a semi-silvered mirror at the top) and/or at the sides that aren't the top or bottom of the Transparent Photovoltaic Material (in conjunction with a semi-silvered mirror at the top). Multiple transparent photovoltaic materials may be used by stacking one atop the other. Arrangement of the stacked transparent photovoltaic materials can be inverted from one individual material to another such that one layer's light reactive “face” is facing away from the light source and the layer after it has the reactive layer facing the light source and so on and so forth.

There are various methods of manufacture, including adhering the mirrors to the Transparent PV Material with a very strong but transparent adherent. Obviously there would be space for the electrical contacts to connect between the mirrors, or the mirrors could be used as electrical contacts themselves.

There are various concepts that could used to improve the function and efficiency of the photovoltaic apparatus including: use of the solid mirrors as electrical contacts; use of transparent conducting oxides as Electrical Contacts; use of glass, or some other Transparent material to separate the conductive bits of the apparatus. Make the Bottom contact of a Transparent Photovoltaic material a mirror by having the bottom PV layer (either the P or N layer) directly coated and be attached to the Mirror. Design the Face of the Apparatus that is most directly positioned towards the Light source to be either convex (as in convex lenses) or Fresnelled (as in Fresnel lenses), it could be a semi-silvered mirror and/or the Transparent Photovoltaic Material itself.—

Another concept is the use of a photon collecting dish, composed of a lens that bends light into the collector Then the collector itself which would have many light directors (fiber-optic wires) that the photons would be sent through. The collector could have the appearance of a snow cone in that there is a roundish “top” (which bends light into the collector) and a conical “body” (which the Fiber-optic wires are part of).

Added concepts include the use of light reflective electrical resistors to separate the conductive bits of the apparatus. Use of tubes that run coolant (convection coolant) through them and are attached to the apparatus such that they do not hinder the take up of light and thus the performance of the apparatus but cool the apparatus—

Use of used coolant for useful (co-generative) means, such as turning a turbine and/or (should the coolant be water) as heated water—

An object of the present invention is to provide a Photovoltaic apparatus that is in operation more efficient with the amount of light it receives than prior art through the use of internal reflection.

### BRIEF DESCRIPTION OF DRAWINGS

The above and/or other aspects of the present invention will become apparent and more readily appreciated from the following description of the exemplary embodiments, taken in conjunction with the accompanying drawings in which:

FIG. 1 is a schematic perspective view of a photovoltaic apparatus utilizing internal reflection according to the present invention;

FIGS. 2-3 are schematic views showing constructions of the present invention; and

FIG. 4 is a view showing an application of the present invention.

### DETAILED DESCRIPTION OF THE INVENTION

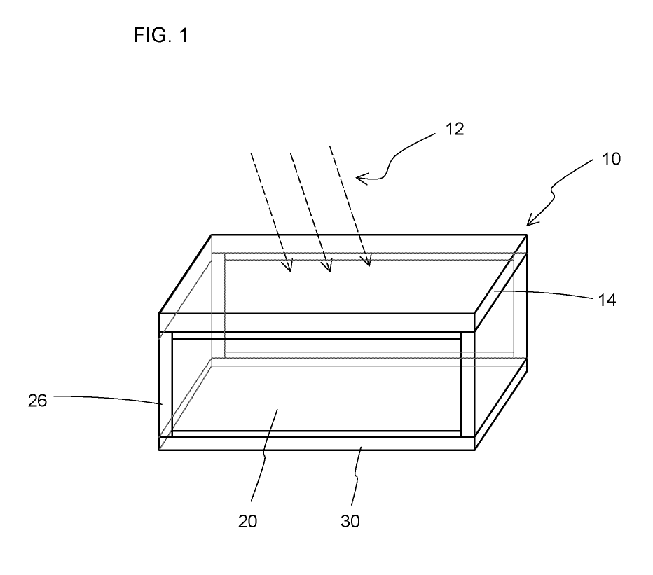

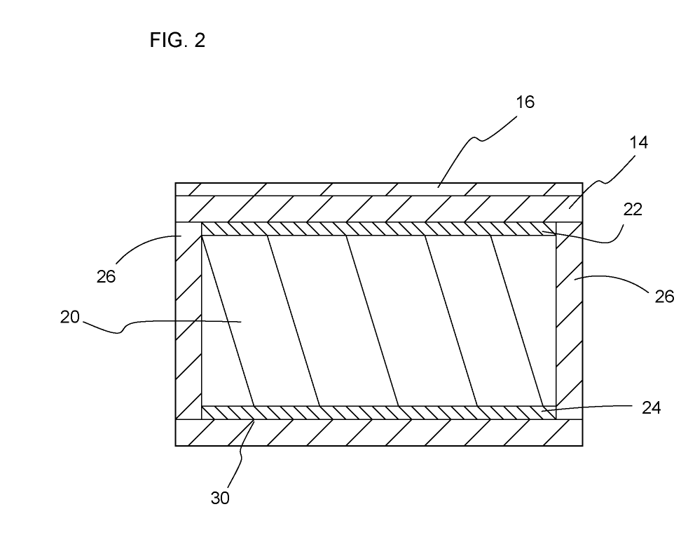

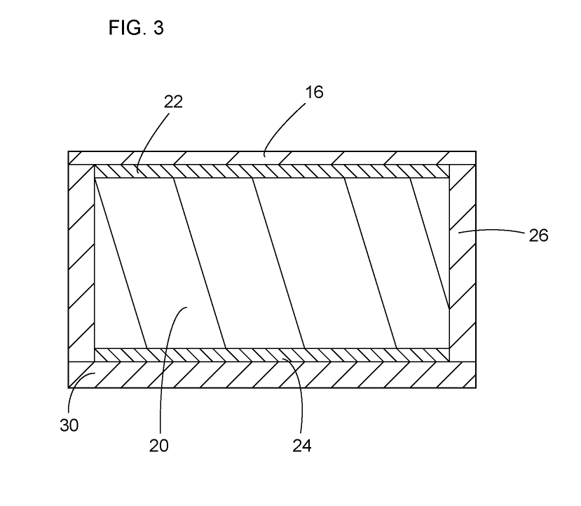

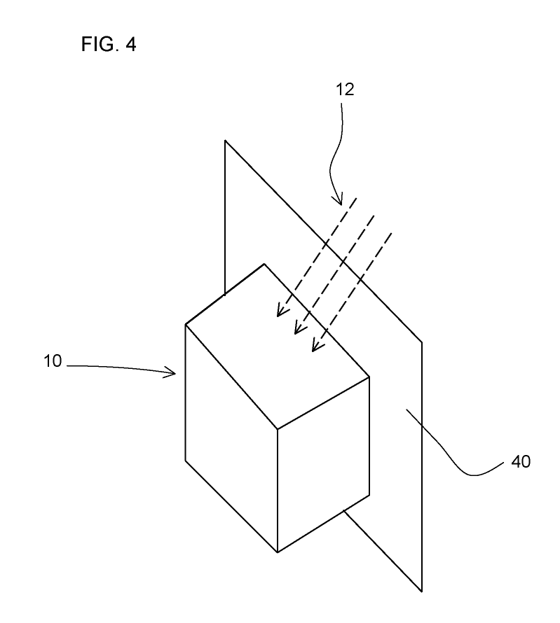

As shown in FIGS. 1-4, a photovoltaic apparatus 10 utilizing internal reflection comprises a semi-transparent photovoltaic panel 20 to absorb a portion of photons 12 from above and to produce electrical energy. The panel 20 has a first conducting surface 22 on the top thereof facing upwards and a second conducting surface 24 at the bottom thereof facing downwards. The apparatus 10 further comprises a bottom mirror 30 to reflect the remaining photons from the photovoltaic panel 20, whereby the remaining photons bounce up and down between the top and bottom mirrors to increase production of the electrical energy.

The first conducting surface 22 has transparent electrical contacts which preferably are transparent conducting oxides. The second conducting surface 24 also has transparent electrical contacts which preferably are transparent conducting oxides. The bottom mirror 30 is semi-silvered. The photovoltaic apparatus 10 further comprises a side mirror 26 on each side of the panel 20 In a preferred version, the photovoltaic apparatus 10 is attachable to a window 40. The photons 12 enter the photovoltaic apparatus through a fiber optic wire 16.

In a preferred embodiment, the photovoltaic apparatus 10 comprises a semi-silvered top mirror 14 to allow photons 12 to pass through, a semi-transparent photovoltaic panel 20 to absorb a portion of the photons and to produce electrical energy so the panel 20 has a first conducting surface 22 on the top thereof facing upwards and a second conduction surface 24 at the bottom thereof facing downwards, and a bottom mirror 30 to reflect the remaining photons from the photovoltaic panel 20, whereby the remaining photons bounce up and down between the top and bottom mirrors to increase production of the electrical energy.

In all embodiments components that cannot be manufactured directly onto the others may be adhered to the others through the application and usage of non-electric-conducting transparent adhesives or connected in other means such that the apparatus may hold together in such a way that the apparatus is functional.

In one embodiment the Transparent conducting oxide is covered by a protective transparent nonconductive layer as the sun-facing surface. Beneath the Transparent conducting oxide is the Transparent Photovoltaic material that generates the electricity that is run in circuit from the TCO to the Bottom Side Contact—which may be a TCO or A Reflective Metal Plate and which sits beneath the Transparent Photovoltaic Material. should the bottom side contact be a TCO another protective glass layer is necessary. This is one layer, note however that the order of the components of the layer can be reversed, with the sun reactive photovoltaic material facing the bottom side.

In Another Embodiment—which follows the first embodiment until the bottom side contact—the bottom contact is a Transparent Conducting Oxide, Beneath which is a Semi-silvered mirror—a mirror that you can see through but still serves as a mirror.

In yet another Embodiment—which follows the first embodiment except that there are multiple layers—in which each layer's contacts are TCO's and may have a thin nonconductive transparent protective material between each successive layers' TCO contact that would otherwise touch the other successive layer's contact, except for the layer that serves as the bottom side which uses a reflective material either after its TCO or as its bottom side contact.

In a fourth embodiment there is a semi-silvered mirror as the sun-facing side, directly beneath which is a TCO. Directly beneath the TCO is the Transparent Photovoltaic Material, Directly Beneath Which is The bottom Side contact and reflective material. In the case that there are multiple layers only the layer that serves as the sun-facing side will start with a Semi-Silvered Mirror, between each successive layers' TCO there is a transparent nonconductive material to separate current and charges, and the layer that serves as the bottom side will either have a TCO—directly beneath which is a Semi-slivered mirror—or a reflective material that serves as the bottom side contact.

A fifth embodiment collects photons into fiber optic wires which direct photons into a photovoltaic apparatus.

A sixth embodiment takes any of the previous embodiments and adds side mirrors to the far sides of the apparatus—not the bottom or sun-facing sides—so as to better bounce the light within the apparatus. the contacts could connect with the conductors that lead to the wiring where the contact meets the side mirrors, or the mirrors themselves could serve as conductors, separated from opposite charged bits by light-reflective resistors.

A seventh embodiment takes any of the previous embodiments and uses convection cooling to cool them. there are convection coolant tubes that either run through the apparatus, under the apparatus—but directly touching the apparatus—or running along the far sides of the apparatus—while directly touching the apparatus. The convection coolant cools the apparatus by absorbing heat from the apparatus through the contact made by the tube and the apparatus and, by traveling through the apparatus, transporting the heat elsewhere. By absorbing the heat of the apparatus the coolant heats, expanding. When this effect is coupled with the effect of moving the coolant it would be easy to turn a turbine at the end of the tubes, and should the tubes converge into a single tube before the turbine it would be easy and effective, moreover heated coolant could have applications as a useful product, such as when the coolant is water. heated water could be used as bath water or steam, given the severity of the heating of course.

An eighth embodiment is when a 2 or 3 dimensional electric contact grid is created, with photovoltaic material surrounding it, and another electrical contact surrounding that. surrounding all of it is a protective transparent covering.

A ninth embodiment is when the 2-D/3-D PV grid is made of TCOs and Transparent Photovoltaic materials, making the entire apparatus transparent.

A tenth embodiment is any combination of the preceding embodiments.

This includes any, and all, PV apparatus that, in any way, use reflection to increase the amount of convertible, and/or converted, light given the same amount of light, and over the same amount of time, as another PV apparatus not utilizing light reflection. The number of reflections is not limited, save for the minimal and mandatory one reflection. The light may find its way into the cell by means of but not limited to, direct sun exposure, photon feeding from fiber optic wires, reflection, and/or refraction.

The reflections must occur within the apparatus and/or in such a way that light is reflected into the apparatus and, for the most part, to keep the light within the apparatus. In other words, the reflectors are, for the most part, within the apparatus; however the reflectors may be out side of the apparatus so long as the reflectors that are out side of the apparatus are not connected to the apparatus.

In the case of the 2D/3D PV grid, which could be applicable anywhere a wire mesh is used as a form of the construction of an object. In the case of the 2D PV grid it could replace a standard wire mesh fence in residential construction. The goal is increased areas employed for the generation of electricity, after all, why should PV generation be confined to the roof's of surfaces when sunlight strikes front porches and campsites too.

Design Specifications
A) Minimal requirements
   1) photovoltaic material
   2) mirror(s) of some sort, really any type material that is used in/for any type of reflection will do
   3) TCO as contacts where necessary, logical, cost effective, and/or wanted.
B) Preferred standards
   1) fully transparent photovoltaic material
      a) Each layer of the material would be flipped so that the sun-reactant sides faced each other (first layer from the top would have the sun-reactant side facing the top and the last layer from the top would have the sun reactant side facing the bottom of the cell.

One embodiment is a semi-silvered mirror(s), mirror(s), resistor(s) fully transparent medium in the form of convex/Fresnel/blazed lens(es), some form of UV protection, coolant,) heat-conducting and electrical resisting hollow tube(s) for coolant containment, turbine/generation mechanism and housing, fiber optics and fiber optic wires, additional and unaffiliated or stand-alone qualifiers, 2-D/3-D PV grid suspended/enveloped in or not suspended/enveloped in transparent material, solid or transparent (even partially).

The wires themselves are applicable in such things as wire mesh making for things like, but not limited to, the following: covering a car, making cloths, making a wire mesh bit for bug proofing a patio, porch, or other applicable area or thing.

Concerning design layout there are probably many different combinations of the components disclosed in the documents that were neither described in this paper nor illustrated in a submitted figure, however I the specification touched base with the most important ones, those that can be defined as my apparatus by the concepts and components disclosed within this application are still subject to protection by said application. Any and all transparent materials that come before the PV elements could be used to protect the cell/panel from UV rays and/or be used as another PV layer. Also, if the transparent bits need be attached solidly to another object, possibly another transparent object, then the use of significantly transparent industrial grade plastic polymer adhesives may be used to hold the cell, and the transparent bits, together. Moreover, all, and I repeat all, transparent PV layers must be covered in a TCO layer thick enough to serve the needs that the contacts must. All PV layers may be inverted so that the corresponding part of a PV layer is facing the neighboring PV layer and such that the first layer of PV material has the sun reactant side facing the sun and such that the last layer of PV material has the sun reactant side facing away from the sun unless its spacial relation in regards to the position of the sun were changed to make the last layer the sun facing layer. All lenses may be blazed, just as all lateral-most transparent faces can be. Most preferably all non-PV transparent materials should reflect off little to none of the light it receives.

For all apparatus that have solid photovoltaic material as opposed to semi- or fully transparent photovoltaic material the layout would basically comprise of the following components listed from top to bottom, all components that would be lateral will be disclosed last in this paragraph: a transparent conducting oxide, the PV layer with too many electrons, the layer with too little electrons, the bottom contact, mirrors that may also serve as current conductors may be placed in-between the differentiating individual solar cell apparatus at every lateral face of the TCO such that light may reflect off of the mirrors and possibly into the apparatus's light reactant layer. (The lateral face is any edge or face which is not part of a base). Although not necessary as per the one minimal reflection rule, due to the unavoidable percentage of light that is ironically reflected by the solid photovoltaic material, a semi-silvered mirror with the “mirrored” face facing towards the inside of the cell and possibly blazed and/or shaped like a lens could come first.

As there are many possible combinations of the components disclosed within this document, with regards to end products utilizing photovoltaic materials, I will not attempt to list them all, rather I will break them into a few general categories, with some of the characteristics in one and others in others, keep in mind that clever types will attempt to use these categories as justification to a “my invention is different enough” statement in regards to the order, usage, or placing of the components disclosed within this document. I'm here to say that these categories are mentioned only for the sake of saving me time and frustration and their not mentioned for the purpose of distinguishing an all-encompassing palpable bracket of designs. Once again these categories will only give simple broad spectrum coverage on an exponentially extensive expansive range of possibilities. All categories marked with a carrot (̂) are ones that could apply to either solid or semi/fully transparent PV material utilizing apparatus, maybe even both.

Category 1̂: Photon Fed Apparatus

This includes any photon fed apparatus utilizing reflection within the photon fed piece of equipment that generates electrical energy from said piece of equipment with the photons derived from the means of photon feedature. The apparatus can be photon fed by the sun via sun exposure, fiber optic wires, or any combination of the mentioned or possible means of photon feedature, so long as it receives photons, at least partially, indirectly. Category 2: 2-ways—This includes Any PV apparatus that utilizes transparent PV materials, and a semi-silvered mirror. Category 3: This includes Any PV apparatus that utilizes transparent PV materials, and mirrors. Category 4: pimple panel forming—This includes Any PV apparatus that utilizes transparent PV materials, and lenses. The ‘pimple panel forming’ title referring to the theorized view one might obtain of the apparatus if combined with others of similar caliber to create a panel with which one might observe. Category 5: cake-like—This includes Any PV apparatus that utilizes transparent PV materials, and is formatted in such a way that the materials form sections such as the layers of a cake separated only by the contacts that keep the electricity on the circuit, although they may be separated by other components. Keep in mind that the layers may be inverted. Category 6: This includes Any PV apparatus that utilizes transparent PV materials, and utilizes laterally placed mirrors (in regards to the diverse range of possible transparent materials to be used in the apparatus). Keep in mind that the mirrors may also serve as current conductors. Category 7̂: resistant—This includes Any

PV apparatus that utilizes resistors to separate differentiating electrical charges. When connected or attached to transparent materials, the sides of the resistor(s) that touch and face the transparent material should be reflective but not conductive to electricity, given that this option is the best option, or even an option at all (in terms of feasibility).

Category 8̂: insured—This includes Any PV apparatus that utilizes either UV or heat protection(˜), or even both. This may be derived in the form of convection cooling, which could also be exploited to derive further benefits in one form or another. Category 9̂: efficient to the extreme—This includes Any PV apparatus that utilizes, when in panel form, depleted coolant, or in other words hot coolant, to derive electricity, by turning a turbine or other such mode of electrical generation, or in the case of water, to be used as heated bath, pool, or other-areas-of-applicable-usage water. Category 10̂: gridlocked—This includes Any PV apparatus that utilizes the disclosed PV grid forms (2 and/or 3-D), either transparent (even partially), solid, fully suspended/encased in a transparent medium, or any combination of the three. Category 11: complex—This includes any PV apparatus that utilizes one or more components/characteristics of any one or more PV apparatus that could fall into any other category. It is basically a PV apparatus that uses any variant of any quantity of combinations of the other categories components or specialties

Following are descriptive examples of components in order from top to bottom (If necessary, significantly transparent industrial grade plastic polymer adhesives may be used to hold the cell together.) I claim ownership to all variants of all components listed that I may per requirements set forth within this document.

Bare Minimum

### Single Cell

(A)—There are four components; listed in order from top to bottom they are: semi-silvered mirror (with mirrored face facing the cell), TCO, solid PV material(s), bottom contact. If necessary, significantly transparent industrial grade plastic polymer adhesives may be used to hold the cell together.

### Panel

(A)—It May simply be a very, very large (in terms of x and y-axis directional dimensions) single cell with wires attached to outer and bottom contacts and the whole thing wrapped in a resistor with the wires poking out. The wires should be coated with a resistor too. It could also be multiple single cells with a current conductor between them which serves to also separate the cells. The panel would still be wrapped in a resistor material with the resistor-coated wires poking out.

If fully transparent PV materials are used

### Single Cell

(A)—If the fully transparent PV materials are used, there would be 3 components; listed in order from top to bottom they are: TCO, fully transparent PV material(s), mirror/bottom contact. If necessary, significantly transparent industrial grade plastic polymer adhesives may be used to hold the cell together.

(B)—If the fully transparent PV materials are used, there would be 4 components; listed in order from top to bottom they are: TCO, fully transparent PV material(s), TCO, Semi-silvered mirror (mirror facing the PV materials). If necessary, significantly transparent industrial grade plastic polymer adhesives may be used to hold the cell together.

### Panel

(A)—It May simply be a very, very large (in terms of x and y-axis directional dimensions) single cell with wires attached to outer and bottom contacts and the whole thing wrapped in a resistor with the wires poking out. The wires should be coated with a resistor too. It could also be multiple single cells with a current conductor between them which serves to also separate the cells and possibly work as (a) mirror(s). The panel would still be wrapped in a resistor material with the resistor-coated wires poking out.
(B)—It May simply be a very, very large (in terms of x and y-axis directional dimensions) single cell with wires attached to outer and bottom contacts and the whole thing wrapped in a resistor with the wires poking out. The wires should be coated with a resistor too. It could also be multiple single cells with a current conductor between them which serves to also separate the cells and possibly work as (a) mirror(s). The panel would still be wrapped in a resistor material with the resistor-coated wires poking out.

Moderately intricate designs (in all of the designs fully transparent PV materials are used)

### Single Cell

(A)—Semi-silvered mirror (mirror facing into the cell), TCO, fully transparent PV materials, mirror/bottom contact
(B)—Semi-silvered mirror (mirror facing into the cell), TCO, fully transparent PV materials, mirror/bottom contact, and on each side there are mirrors/current conductors separated from the bottom contact by resistors which would more than likely have to be coated with a very dense and highly reflective paint on the side that faces into the cell
(C)—Concave and/or Fresnel lens(es), Semi-silvered mirror (mirror facing into the cell), TCO, fully transparent PV materials, mirror/bottom contact
(D)—Concave and/or Fresnel lens(es), Semi-silvered mirror (mirror facing into the cell), TCO, fully transparent PV materials, mirror/bottom contact, and on each side there are mirrors/current conductors separated from the bottom contact by resistors which would more than likely have to be coated with a very dense and highly reflective paint on the side that faces into the cell
(E)—Concave and/or Fresnel lens(es), Semi-silvered mirror (mirror facing into the cell), TCO, fully transparent PV materials, mirror/bottom contact, and on each side (and all the way up to the lens(es) to the point where they could block light waves from entering a cell next to it, but not so far as to where they would actually block the waves) there are mirrors/current conductors separated from the bottom contact by resistors which would more than likely have to be coated with a very dense and highly reflective paint on the side that faces into the cell
(F)—Chemically or mechanically blazed lens(es) surface, Concave and/or Fresnel lens(es), Semi-silvered mirror (mirror facing into the cell), TCO, fully transparent PV materials, mirror/bottom contact
(G)—Chemically or mechanically blazed lens(es) surface, Concave and/or Fresnel lens(es),Semi-silvered mirror (mirror facing into the cell), TCO, fully transparent PV materials, mirror/bottom contact, and on each side there are mirrors/current conductors separated from the bottom contact by resistors which would more than likely have to be coated with a very dense and highly reflective paint on the side that faces into the cell
(H)—Chemically or mechanically blazed lens(es) surface, Concave and/or Fresnel lens(es), Semi-silvered mirror (mirror facing into the cell), TCO, fully transparent PV materials, mirror/bottom contact, and on each side (and all the way up to the lens(es) to the point where they could block light waves from entering a cell next to it, but not so far as to where they would actually block the waves)there are mirrors/current conductors separated from the bottom contact by resistors which would more than likely have to be coated with a very dense and highly reflective paint on the side that faces into the cell Panel

All of the not-side-mirrored single cell designs could be:
(A)—It May simply be a very, very large in terms of x and y-axis directional dimensions) single cell with wires attached to outer and bottom contacts and the whole thing wrapped in a resistor with the wires poking out. The wires should be coated with a resistor too. It could also be multiple single cells with a current conductor between them which serves to also separate the cells. The panel would still be wrapped in a resistor material with the resistor-coated wires poking out.

All of the not-side-mirrored single cell designs that also have lens(es) tops could be:
(A)—It May simply be a very, very large (in terms of x and y-axis directional dimensions) single cell with wires attached to outer and bottom contacts and the whole thing wrapped in a resistor with the wires poking out. The wires should be coated with a resistor too. The whole thing could have one large lens(es) or many, many smaller lens(es). It could also be multiple single cells with a current conductor between them which serves to also separate the cells. The panel would still be wrapped in a resistor material with the resistor-coated wires poking out. Here the only choice is to have as many lens(es) as there are cells.

All of the side-mirrored single cell designs could be
(A)—It May simply be a very, very large (in terms of x and y-axis directional dimensions) single cell with wires attached to outer and bottom contacts and the whole thing wrapped in a resistor with the wires poking out. The wires should be coated with a resistor too. It could also be multiple single cells with the mirrors serving as current conductors between the cells which serve to also separate the cells. The panel would still be wrapped in a resistor material with the resistor-coated wires poking out.

All of the side-mirrored single cell designs that also have lens(es) tops could be;
(A)—It May simply be a very, very large (in terms of x and y-axis directional dimensions) single cell with wires attached to outer and bottom contacts and the whole thing wrapped in a resistor with the wires poking out. The wires should be coated with a resistor too. The whole thing could have one large lens(es) or many, many smaller lens(es). It could also be multiple single cells with the mirrors serving as current conductors between the cells which serve to also separate the cells. The panel would still be wrapped in a resistor material with the resistor-coated wires poking out. Here the only choice is to have as many lens(es) as there are cells.

Very Intricate Designs

Single cell (If necessary, significantly transparent industrial grade plastic polymer adhesives may be used to hold the cell together).
(A)—Chemically or mechanically blazed lens(es) surface, Concave and/or Fresnel lens(es), Semi-silvered mirror (mirror facing into the cell), TCO, fully transparent PV materials, mirror/bottom contact, and on each side (and all the way up to the lens(es) to the point where they could block light waves from entering a cell next to it, but not so far as to where they would actually block the waves), should the mirrors be used as current conductors they would most likely have to be extended out to the sides by an amount equal to the radius of the convection coolant tube(s), the mirrors/current conductors are separated from the bottom contact by resistors which would more than likely have to be coated with a very dense and highly reflective paint on the side that faces into the cell and would most likely have to extend out to the sides by an amount equal to the radius of the convection coolant tube(s) just to be safe that the side and bottom mirrors do not touch or that any unnecessary electricity is discharged into the convection coolant tubes (The convection coolant tubes would be stacked one on top of the other in between the cells and their contacts in a panel).

### Panel

(A)—It May simply be a very, very large (in terms of x and y-axis directional dimensions) single cell with wires attached to side and bottom current conductors and the whole thing wrapped in a resistor with the wires poking out and then wrapped by multiple stacked convection coolant tubes, again with the wires poking out. The wires should be coated with a resistor too. The whole thing could have one large lens(es) or many, many smaller lens(es). It could also be multiple single cells with the mirrors serving as current conductors between the cells and between them are multiple stacked convection coolant tubes which serve to cool the cells/panel and help separate the individual cells. The whole panel would be wrapped in a resistor with the wires poking out and then wrapped by multiple stacked convection coolant tubes, again with the wires poking out. The wires should be coated with a resistor too. Here the only choice is to have as many lens(es) as there are cells. There is one inflow into each layer of tubes that branched off from a main tube. There is one outflow leading from the panel for each layer of tubes that come together to form the main tube.
(B)—It May simply be a very, very large (in terms of x and y-axis directional dimensions) single cell with wires attached to side and bottom current conductors and the whole thing wrapped in a resistor with the wires poking out and then wrapped by multiple stacked convection coolant tubes, again with the wires poking out. The wires should be coated with a resistor too. The whole thing could have one large lens(es) or many, many smaller lens(es). It could also be multiple single cells with the mirrors serving as current conductors between the cells and between them are multiple stacked convection coolant tubes which serve to cool the cells/panel and help separate the individual cells. The whole panel would be wrapped in a resistor with the wires poking out and then wrapped by multiple stacked convection coolant tubes, again with the wires poking out. The wires should be coated with a resistor too. Here the only choice is to have as many lens(es) as there are cells. There is one inflow into each layer of tubes that branched off from a main tube. There is one outflow leading from the panel for each layer of tubes that come together to form the main tube. Proximal to the start of the main tube from the outflow tubes is a hydroelectric generator adaptor piece. The coolant flowing into the adaptor flows along the tubing in a descending funnel like shape. The shape forms an object much shaped like a bowl and at the bottom the tubing heads straight down until turning in another direction. In the “bowl” the tubes have a long, thick line cut through the tubes' side that faces into the bowl that allows the coolant to turn a screw-like spinning-top-shaped turbine to generate even more electricity. The adaptor would be encased by a cube that has holes for the inflow/outflow sides for the main tube, and that has resistor coated-wires protruding out of the cube from the generator that serve to take the charge someplace useful. From the adaptor's outflow side, the tubing and its goes through a cooling process such as, but not limited to, simply having the tubing run through the lowest layer of the house to benefit from the air conditioning, or having the tubing run through the house to benefit from the air conditioning and to pass through a freezer of sorts. Finally the main tube is connected to a pump that keeps the coolant moving throughout the whole process and helps to move the coolant up vertically in areas where it is absolutely necessary to have “up” turning tubing.

Fiber Optic Wire Fed Designs

Single cell (If necessary, significantly transparent industrial grade plastic polymer adhesives may be used to hold the cell together).
(A)—Anywhere convenient is where fiber optic collectors can be placed, for optimal efficiency they must be placed somewhere of high and extremely prolonged sun exposure. The fiber optic wires are covered in a reflective material except for the bits in the fiber optic collectors. These wires run into the cell's mirror/current conductive side, bottom, and/or top faces which allows them to empty their photons into the cell. Thus the cell is fed by fiber optic wires.

### Panel

(A)—Anywhere convenient is where fiber optic collectors can be placed, for optimal efficiency they must be placed somewhere of high and extremely prolonged sun exposure. The fiber optic wires are covered in a reflective material except for the bits in the fiber optic collectors. Leading from the collectors; these wires are in clusters/bundles that branch off to the different cells that make up the loosely defined panel. These wires run into the cell's mirror/current conductive side, bottom, and/or top faces which allows them to empty their photons into the cell. Thus the cell is fed by fiber optic wires.

Visual Examples—Details for the Figures of the Provisional Application.

The Provisional Application No. 61/269,724 filed Jun. 29, 2009 and all of its drawings are incorporated by reference into this utility application. Please keep in mind all of the figures feature some of the components includable or applicable and that it would be very near impossible to come up with all the different combinations and variations. Also, where the “lens” component is you will see a convex lens, or at least part of one, please note that there could be any lens there. All mirrored faces face INTO the apparatus, this is especially important for the fully transparent PV material utilizing PV apparatus. Resistors extend to block the contacts from each other (so that charges don't get mixed together) and so that contacts don't touch the convection cooling component(s). the convection cooling component(s) may be varied in shape, number, size, volume, and any other applicable dimension, or description, given design specifications.

Figures (they are numbered)

1. conventional PV apparatus plus modifications to protect it per requirements set forth in this application, cross sectional general example design 1

2. conventional PV apparatus plus modifications to protect it per requirements set forth in this application, cross sectional general example design 2

3, conventional PV apparatus plus modifications to protect it per requirements set forth in this application, cross sectional general example design 3

4. conventional PV apparatus plus modifications to protect it per requirements set forth in this application, cross sectional general example design 4

5. simple fully-transparent-PV-elements-utilizing PV apparatus, cross sectional general example design 1

6. simple fully-transparent-PV-elements-utilizing PV apparatus, cross sectional general example design 2

7. simple fully-transparent-PV-elements-utilizing PV apparatus, cross sectional general example design 3

8. simple fully-transparent-PV-elements-utilizing PV apparatus, cross sectional general example design 4

9. simple fully-transparent-PV-elements-utilizing PV apparatus, cross sectional general example design 5

10. simple fully-transparent-PV-elements-utilizing PV apparatus, cross sectional general example design 6

11. intricate fully-transparent-PV-elements-utilizing PV apparatus, cross sectional general example design 1

12. intricate fully-transparent-PV-elements-utilizing PV apparatus, cross sectional general example design 2

13. intricate fully-transparent-PV-elements-utilizing PV apparatus, cross sectional general example design 3

14. intricate fully-transparent-PV-elements-utilizing PV apparatus, cross sectional general example design 4

15. photon-fed PV apparatus, cross sectional general example design 1

16. photon-fed PV apparatus, cross sectional general example design 2

17. photon-fed PV apparatus, cross sectional general example design 3

18. photon-fed PV apparatus, cross sectional general example design 4

Components (they are numbered)

All of the following components are numbered. They will also have a description under them that might be in reference to any number of things, the most common of which include: functionality, the importance of its functionality, its importance of it to the relevance of the apparatus's performance and/or eligibility to be included for protection per the requirements set forth within this application, whether or not it is an improvement, how It may be considered an improvement, and necessity for basic function (whether it's a necessity).

1. Solid PV Material

a. Converts photons into electricity, not necessary if fully transparent PV material is available for application.

2. Conventional Solid PV Solar Cell Bottom Contact

a. Serves to direct electrical current of one charge, generally covers the entirety of a face not facing the photon source, necessary for optimal performance

3. Conventional solid PV solar cell outer contact

a. Serves to direct electrical current of one charge, generally takes the form of a flat metal mesh-like grid on the photon source facing face. Not necessary If TCO's are used

4. TCO

a. Short for transparent conducting oxide it works as a light-permeable (transparent) conductor, while not necessary it is preferable to conventional photon facing contacts in use.

5. Semi-Silvered Mirror

a. A transparent material that has been applied with a reflective semi coating such that light may pass through both sides, however during an attempt to permeate through one side the light might find a reflective obstacle. Most definitely preferred to be used whenever possible.

6. Semi-Silvered Mirror, “Mirrored Face” Facing into Apparatus

a. A transparent material that has been applied with a reflective semi coating such that light may pass through both sides, however during an attempt to permeate through one side the light might find a reflective obstacle. In this case the reflective side is facing into the apparatus such that the function becomes to allow light in, and let very little out. Most definitely preferred to be used whenever possible.

7. Convex Lens

a. a lens used to bend light into the cell such as one of this design, would be useful when light strikes the cell at a sharp angle. Most definitely preferred to be used whenever possible.

8. Fresnel Lens

a. a lens used to bend light into the cell such as one of this design, would be useful when light strikes the cell at a sharp angle. Most definitely preferred to be used whenever possible.

9. Resistor

a. resists heat and/or the passage of electrical current through itself Would be useful when the majority of inversely charged materials come into close proximity to one another and/or are touching. It would be put in between the materials.

10. Fiber Optic Wire

a. very useful in photon transfer

11. Reflective Material

a. reflects light (photons)

12. Reflective Material as a Mirror

a. material in the form of a mirror that solely reflects light

13. Reflective Material as a Mirror as a Conductor

a. material in the form of a mirror that reflects light and has the ability to conduct electricity (but preferably not heat)

14. Reflective Material on a Resistor's Face that Faces Transparent Material that is Directly Touching it, and is a Resistor Itself

a. crucial in resistor necessary FTPV apparatus

15. Transparent PV Material

a. Material that functions in such a way that light will permeate through it, and hopefully be absorbed during said process.

16. Lateral Mirrors

a. would work to help create a semi-total internal reflection effect within a

FTPV apparatus.

17. Lateral Mirrors that also Serve as Current Conductors

18. V-shaped semi silvered mirror, “mirrored face” face down

a. The “V” shape will vary depending on the location of the photon source, it works to reflect light received from a specific photon source in a specific direction while still allowing light to permeate through it on one side (without reflective interference)

19. Convection Cooling Tube

a. a hallow tube, made of materials that conduct heat exquisitely but electicity poorly, and happen to hold that heat within it rather properly.

20. Hallow Space for Coolant

a. should be the majority of the tube

21. Convection Coolant

a. any material (preferably fluidic) that conducts heat and moves it elsewhere. Preferably as it heats it expands thus moving faster within its container (in the case of a fluid) which could be use full in the application of said coolant in a co-generative process.

22. 2D/3D PV Grid

May be made of conventional solid or FTPV materials, may employ TCO's, and are much like a wire mesh or

With reference to the prior art patent U.S. Pat. No. 4,663,495, which appears to reference using transparent PV material, uses thin-film, and non-thin-film, uses TCO's both and either as front and/or back contacts. Has a reflective layer laminated or applied at the back of the panel. Has a solar collector at the back of the panel that uses unused heat to heat a fluid. Claimed a method of utilizing a thin film photovoltaic module to filter solar radiation entering a structure having a plurality of walls defining an interior volume, Stacked and/or wave specific PV layers

What is claimed is:

1. A photovoltaic apparatus, comprising:
a semi-transparent photovoltaic panel to absorb a portion of photons from above and to produce electrical energy, wherein the panel has a first conducting surface on the top thereof facing upwards and a second conducting surface at the bottom thereof facing downwards; and
a bottom mirror to reflect the remaining photons from the photovoltaic panel, whereby the remaining photons bounce upward to be absorbed by the second conducting surface to increase production of the electrical energy.

2. The photovoltaic apparatus of claim 1, wherein the first conducting surface has transparent electrical contacts.

3. The photovoltaic apparatus of claim 2, wherein the electrical contacts are transparent conducting oxides.

4. The photovoltaic apparatus of claim 1, wherein the second conducting surface has transparent electrical contacts.

5. The photovoltaic apparatus of claim 4, wherein the electrical contacts are transparent conducting oxides.

6. The photovoltaic apparatus of claim 1, wherein the bottom mirror is semi-silvered.

7. The photovoltaic apparatus of claim 1, further comprising a side mirror on each side of the panel.

8. The photovoltaic apparatus of claim 1, wherein the photovoltaic apparatus is attachable to a window.

9. The photovoltaic apparatus of claim 1, wherein the photons enter the photovoltaic apparatus through a fiber optic wire.

10. A photovoltaic apparatus, comprising:
a semi-silvered top mirror to allow photons to pass through;
a semi-transparent photovoltaic panel to absorb a portion of the photons and to produce electrical energy, wherein the panel has a first conducting surface on the top thereof facing upwards and a second conduction surface at the bottom thereof facing downwards; and
a bottom mirror to reflect the remaining photons from the photovoltaic panel, whereby the remaining photons bounce up and down between the top and bottom mirrors to increase production of the electrical energy.

11. The photovoltaic apparatus of claim 10, wherein the first conducting surface has transparent electrical contacts.

12. The photovoltaic apparatus of claim 11, wherein the electrical contacts are transparent conducting oxides.

13. The photovoltaic apparatus of claim 10, wherein the second conducting surface has transparent electrical contacts.

14. The photovoltaic apparatus of claim 13, wherein the electrical contacts are transparent conducting oxides.

15. The photovoltaic apparatus of claim 10, wherein the bottom mirror is semi-silvered.

16. The photovoltaic apparatus of claim 10, further comprising a side mirror on each side of the panel.

17. The photovoltaic apparatus of claim 16, wherein the photovoltaic apparatus is attachable to a window.

18. The photovoltaic apparatus of claim 10, wherein the photons enter the photovoltaic apparatus through a fiber optic wire.
